(19) United States
(12) Patent Application Publication
(10) Pub. No.: US 2002/0093093 A1
(43) Pub. Date: Jul. 18, 2002

(54) Semiconductor package with stacked dies

(76) Inventor: Jong Sik Paek, Kwangju-shi (KR)

Correspondence Address: STETINA BRUNDA GARRED & BRUCKER, 75 ENTERPRISE, SUITE 250, ALISO VIEJO, CA, 92656, US

(21) Appl. No.: 10/044,141

(22) Filed: Jan. 11, 2002

(30) Foreign Application Priority Data
Jan. 15, 2001 (KR) 2001-02160

(51) Int. Cl. H01L 23/34

(52) U.S. Cl. 257/723; 257/690; 257/692; 257/737; 257/773

(57) ABSTRACT

A semiconductor package comprising a plurality of leads. Each of the leads defines opposed first and second surfaces, and a third surface which is also disposed in opposed relation to the second surface and laterally offset outwardly relative to the first surface. The semiconductor package further comprises first and second semiconductor dies which each define opposed top and bottom surfaces. Disposed on the top surface of the first semiconductor die are a plurality of bond pads, with bond pads also being disposed on the bottom surface of the second semiconductor die. The bond pads of the first semiconductor die are electrically connected to respective ones of the first surfaces of the leads through the use of conductive bumps. The conductive bumps are also used to electrically connect the bond pads of the second semiconductor die to respective ones of the second surfaces of the leads. An encapsulating portion is applied to and at least partially encapsulates the leads, the first and second semiconductor dies, and the conductive bumps.

### CROSS-REFERENCE TO RELATED APPLICATIONS

The present application claims priority to Korean Patent Application No. 2001-02160 entitled SEMICONDUCTOR PACKAGE filed Jan. 15, 2001.

### STATEMENT RE: FEDERALLY SPONSORED RESEARCH/DEVELOPMENT

(Not Applicable)

### BACKGROUND OF THE INVENTION

1. Field of the Invention

The present invention relates generally to semiconductor packages, and more particularly to a semiconductor package including a pair of semiconductor dies which are each electrically connected to the leads of the semiconductor package in a manner facilitating a reduction in the size of the semiconductor package.

2. Description of the Related Art

As is well known in the electrical arts, recent advances in semiconductor package technology have led to the development of packaging techniques which provide for the continuing miniaturization of the semiconductor package. These advancements have also led to the development of a wide variety of new and differing types of semiconductor packages. Consistently in high demand are those semiconductor packages which have a high capacity and are capable of performing various functions. However, those currently known semiconductor packages including only a single semiconductor die are limited in their ability to perform multi-functions. To address this limitation, there has been developed in the prior art various semiconductor packages in which semiconductor dies or the semiconductor packages themselves are stacked on each other. However, these semiconductor packages have structural limits attributable to the stacking of the dies or packages therein, and are often of a size which decreases or diminishes their utility in certain applications. The present invention is specifically adapted to address this deficiency, as will be discussed in more detail below.

### BRIEF SUMMARY OF THE INVENTION

In accordance with a first embodiment of the present invention, there is provided a semiconductor package which comprises a plurality of leads. Each of the leads defines opposed first and second surfaces, and a third surface which is disposed in opposed relation to the second surface and laterally offset outwardly relative to the first surface. Also included in the semiconductor package are first and second semiconductor dies which each define opposed top and bottom surfaces. A plurality of bond pads are disposed on the top surface of the first semiconductor die, with bond pads also being disposed on the bottom surface of the second semiconductor die. Conductive bumps are used to electrically connect the bond pads of the first semiconductor die to respective ones of the first surfaces of the leads, and the bond pads of the second semiconductor die to respective ones of the second surfaces of the leads. An encapsulating portion is applied to the leads, the first and second semiconductor dies and the conductive bumps, with the third surface of each of the leads being exposed within the encapsulating portion. In accordance with a second embodiment of the present invention, each of the leads further defines a fourth surface which is disposed in opposed relation to the third surface and laterally offset outwardly relative to the second surface. In the second embodiment, the encapsulating portion is applied to the leads, the first and second semiconductor dies, and the conductive bumps such that the third and fourth surfaces of each of the leads are exposed within the encapsulating portion. The use of conductive bumps to facilitate the electrical and mechanical connection of the first and second semiconductor dies to the leads through the implementation of a flip die bonding technique enables the thickness of the semiconductor package to be substantially reduced.

The present invention is best understood by reference to the following detailed description when read in conjunction with the accompanying drawings.

### BRIEF DESCRIPTION OF THE DRAWINGS

These, as well as other features of the present invention, will become more apparent upon reference to the drawings wherein:

FIG. 1 is a cross-sectional view of a semiconductor package constructed in accordance with a first embodiment of the present invention;

FIG. 1A is a bottom plan view of the semiconductor package shown in FIG. 1;

FIG. 1B is a top plan view of the semiconductor package shown in FIG. 1;

FIG. 2 is a cross-sectional view of a semiconductor package constructed in accordance with a second embodiment of the present invention;

FIG. 3 is a cross-sectional view of a chip stack including multiple semiconductor packages constructed in accordance with the second embodiment of the present invention; and

FIGS. 4A through 4E are cross-sectional views illustrating a sequence of steps which may be employed for manufacturing the semiconductor package of the first embodiment of the present invention.

Common reference numerals are used throughout the drawings and detailed description to indicate like elements.

### DETAILED DESCRIPTION OF THE INVENTION

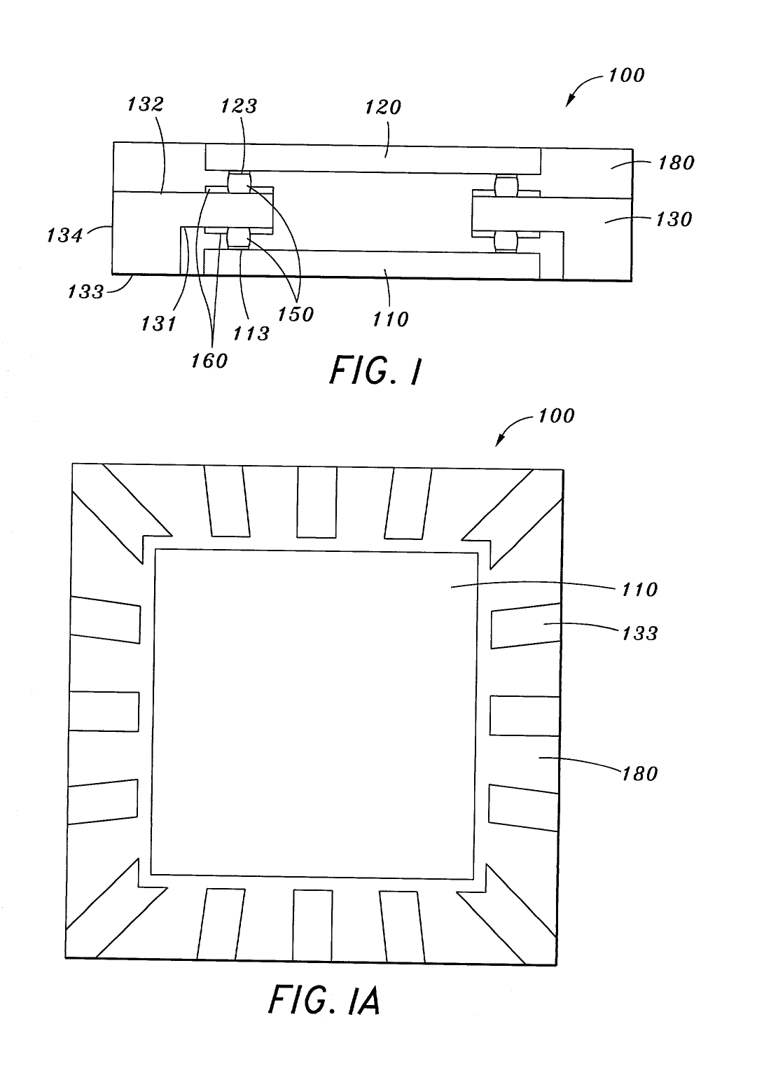

Referring now to the drawings wherein the showings are for purposes of illustrating a preferred embodiment of the present invention only, and not for purposes of limiting the same, FIG. 1 provides a cross-sectional view of a semiconductor package 100 constructed in accordance with a first embodiment of the present invention. The semiconductor package 100 comprises a plurality of identically configured leads 130. Each of the leads 130 defines a generally planar first (lower) surface 131 and a generally planar second (upper) surface 132 which is disposed in opposed relation to the first surface 131. Each lead 130 further defines a generally planar third (lower) surface 133 which is also disposed in opposed relation to the second surface 132 and is laterally offset outwardly relative to the first surface 131. More particularly, the thickness between the second and third surfaces 132, 133 exceeds the thickness between the first and second surfaces 131, 132. The first surfaces 131 of the leads 130 are each preferably formed by a conventional half etching technique using chemical solutions.

As best seen in FIG. 1A, the leads 130 are preferably arranged in the semiconductor package 100 in a generally square pattern such that the leads 130 extend about the periphery of a generally square opening. In this regard, the first and second surfaces 131, 132 of each of the leads extend to such opening. Those of ordinary skill in the art will recognize that differing numbers of leads 130 in differing arrangements may be included in the semiconductor package 100, with the size, shape and arrangement of the leads 130 as shown in FIGS. 1 and 1A being for exemplary purposes only.

As best seen in FIG. 1, coated onto a portion of the first surface 131 of each lead 130 is a protective layer 160. The protective layer 160 is also coated onto a portion of the second surface 132 of each lead 130. More particularly, the protective layer 160 is coated onto that portion of the second surface 132 of each lead 130 which is disposed in opposed relation to the first surface 131 thereof. Thus, the protective layers 160 of each lead 130 extend to the opening collectively defined by the leads 130. The protective layer 160 disposed on the first surface 131 of each lead 130 is formed such that a portion of the first surface 131 is exposed within the approximate center of the protective layer 160, thus defining a lower bump land. Similarly, the protective layer 160 disposed on the second surface 132 of each lead 130 is formed such that a portion of the second surface 132 remains exposed within the approximate center of the protective layer 160, thus defining an upper bump land. The use of the lower and upper bump lands will be discussed in more detail below.

The semiconductor package 100 of the present invention further comprises a first semiconductor die 110 which defines a bottom surface and a top surface which is disposed in opposed relation to the bottom surface. The first semiconductor die 110 further includes a plurality of bond pads 113 which are disposed on the top surface thereof. Also included in the semiconductor package 100 is a second semiconductor die 120 which itself defines a bottom surface and a top surface disposed in opposed relation to the bottom surface. The second semiconductor die 120 is preferably the same size as the first semiconductor die 110, and includes a plurality of bond pads 123 which are disposed on the bottom surface thereof.

In the semiconductor package 100 of the first embodiment, the bond pads 113 of the first semiconductor die are electrically and mechanically connected to respective ones of the first surfaces 131 of the leads 130 by respective ones of a plurality of conductive bumps 150. More particularly, each of the conductive bumps 150 used to electrically and mechanically connect the first semiconductor die 110 to the leads 130 contacts that portion of the corresponding first surface 131 which defines a lower bump land (i.e., is surrounded by the protective layer 160 coated onto the first surface 131). The conductive bumps 150 are also used to electrically and mechanically connect the bond pads 123 of the second semiconductor die 120 to respective ones of the second surfaces 132 of the leads 130. Each of the conductive bumps 150 used to electrically and mechanically connect the second semiconductor die 120 to the leads 130 contacts that portion of the corresponding second surface 132 which defines an upper bump land (i.e., is surrounded by the protective layer 160 coated onto the second surface 132).

In the semiconductor package 100, the material of each conductive bump 150 may be any one of gold, silver, solder, or its equivalent, with the present invention not being limited by any particular material for each conductive bump 150. The material of each protective layer 160 may also be any one of aluminum, titanium, a solder resist, a polyimide or its equivalents, with the present invention also not being limited by any particular material for the protective layers 160. The interface of the conductive bumps 150 to respective ones of the lower and upper bump lands partially defined by the protective layers 160 allows the protective layers 160 to effectively function to prevent the conductive bumps 150 from excessively overflowing during a reflow process preferably used to facilitate the fabrication of the semiconductor package 100. It is preferred that the conductive bumps 150 be formed at each of the leads 130 in the semiconductor package 100 for purposes of preventing a warpage phenomenon in the first and second semiconductor dies 110, 120. However, the conductive bumps can also be formed at the bond pads 113, 123 of the first and second semiconductor dies 110, 120 through the use of evaporation, electroplating, screen printing, or stud bump, with the present invention not being limited by any particular formation methods for the conductive bumps 150.

In the semiconductor package 100, the first and second semiconductor dies 110, 120, the leads 130, and the conductive bumps 150 are each encapsulated by an encapsulant in order to protect the same from the external environment. The hardening of the encapsulant defines an encapsulating portion 180 of the semiconductor package 100. The encapsulating portion 180 is formed such that the third surface 133 of each of the leads 130 and the bottom surface of the first semiconductor die 110 are exposed within the encapsulating portion 180, and in particular the bottom surface defined thereby (FIG. 1A). Thus, the bottom surface of the first semiconductor die 110 is substantially flush with the third surfaces 133 of the leads 130. Exposed in a corresponding side surface of the encapsulating portion 180 is the outermost end 134 of each lead 130 which extends perpendicularly between the second and third surfaces 132, 133 thereof. Additionally, exposed within the top surface defined by the encapsulating portion 180 is the top surface of the second semiconductor die 120 (FIG. 1B). The exposed third surfaces 133 of the leads 130 may be electrically connected to an external device (e.g., a motherboard). Additionally, the exposed third and side surfaces 133, 134 of the leads 130, bottom surface of the first semiconductor die 110 and top surface of the second semiconductor die 120 within the encapsulating portion 180 function as heat sinks which allow for the emission of heat generated by the first and second semiconductor dies 110, 120.

It is contemplated that the first and second semiconductor dies 110, 120 will have identical functions since the semiconductor dies 110, 120 are electrically connected to common leads 130. However, it is also contemplated that the first and second semiconductor dies 110, 120 may have different functions. In this case, the first semiconductor die 110 would be electrically connected to the first surfaces 131 of certain ones of the leads 130, with the second semiconductor die 120 being electrically connected to the second surfaces 132 of certain ones of the leads 130 which are not electrically connected to the first semiconductor die 110. As such, the first and second semiconductor dies 110, 120 would not be electrically connected to any common lead 130. The use of the conductive bumps 150 in the semiconductor package 100 to facilitate the mechanical and electrical connection of the first and second dies 110, 120 to the leads 130 through a flip die bonding technique allows for a reduction in the size or thickness of the semiconductor package 100.

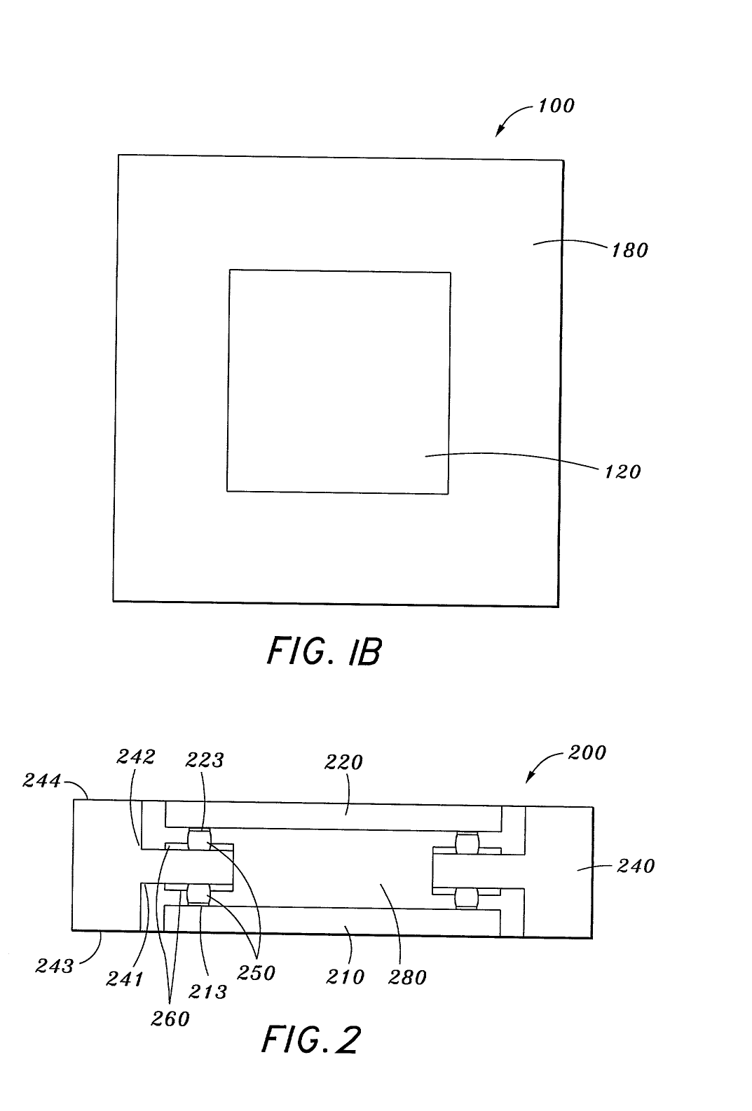

Referring now to FIG. 2, there is shown a semiconductor package 200 constructed in accordance with a second embodiment of the present invention. The semiconductor package 200 of the second embodiment is substantially similar in construction to the semiconductor package 100 of the first embodiment, with only the distinctions being discussed below. As shown in FIG. 2, the semiconductive package 200 comprises a plurality of identically configured leads 240. Each of the leads 240 defines a generally planar first (lower) surface 241 and a generally planar second (upper) surface 242 which is disposed in opposed relation to the first surface 241. Each lead further defines a generally planar third (lower) surface 243 which is laterally offset outwardly relative to the first surface 241, and a generally planar fourth (upper) surface 244 which is disposed in opposed relation to the third surface 243 and is laterally offset outwardly relative to the second surface 242. As such, the thickness between the third and fourth surfaces 243, 244 exceeds the thickness between the first and second surfaces 241, 242.

In the semiconductor package 200, the first and second surfaces 241, 242 of each of the leads 240 are each provided with a protective layer 260 coated thereon in the same manner previously described in relation to the application of the protective layers 160 to the first and second surfaces 131, 132 of each of the leads 130 of the semiconductor package 100. Also included in the semiconductor package 200 are first and second semiconductor dies 210, 220 which are analogous to the first and second semiconductor dies 110, 120 described above. In the semiconductor package 200, conductive bumps 250 analogous to the conductive bumps 150 described above are used to electrically and mechanically connect the bond pads 213 of the first semiconductor die 210 to respective ones of the lower bump lands defined by portions of the first surfaces 241 of the leads 240. Similarly, conductive bumps 250 are used to electrically and mechanically connect the bond pads 223 of the second semiconductor die 220 to respective ones of the bump lands defined by portions of the second surfaces 242 of the leads 240.

Similar to the semiconductor package 100 of the first embodiment, in the semiconductor package 200 of the second embodiment, the bottom surface of the first semiconductor die 210 and third surface 243 of each of the leads 240 are exposed within the bottom surface defined by the encapsulating portion 280, with the bottom surface of the first semiconductor die 210 thus being substantially flush with the third surfaces 243 of the leads 240. The top surface of the second semiconductor die 220 and the fourth surface 244 of each of the leads 240 are exposed within the top surface defined by the encapsulating portion 280 of the semiconductor package 200 of the second embodiment, with the top surface of the second semiconductor die 220 thus being substantially flush with the top surfaces 244 of the leads 240. The outermost ends of the leads 240 are also exposed within the side surfaces defined by the encapsulating portion 280. As will be recognized, both the third surface 243 and fourth surface 244 of each of the leads 240 in the semiconductor package 200 may be electrically connected to an external device.

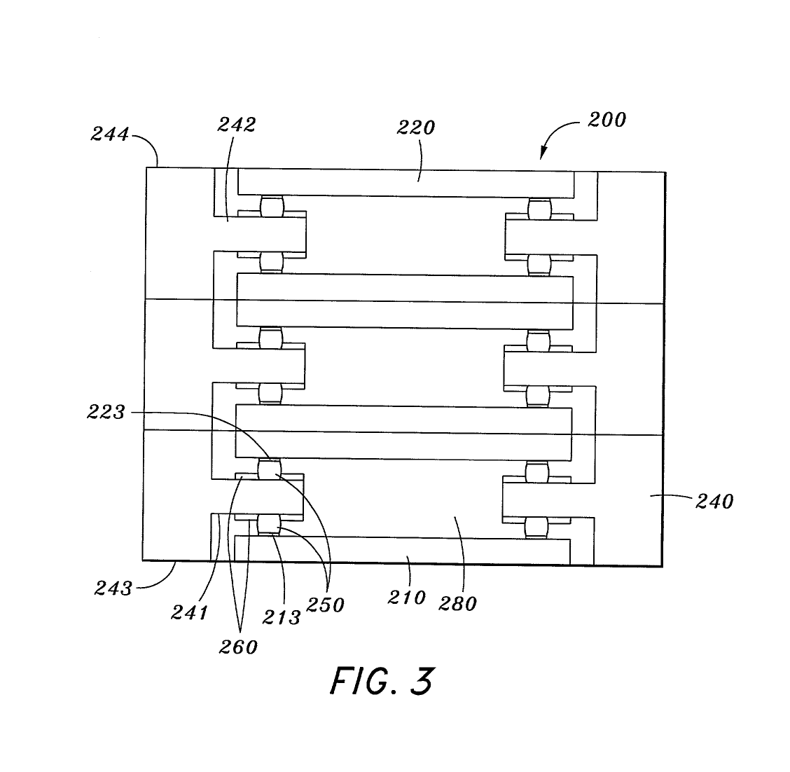

Referring now to FIG. 3, the exposure of the third and fourth surfaces 243, 244 of each of the leads 240 in the encapsulating portion 280 allows semiconductor packages 200 constructed in accordance with the second embodiment to be vertically stacked upon each other in the manner shown in FIG. 3. In this regard, a stacked structure or chip stack using the semiconductor packages 200 of the second embodiment may be formed wherein the third surfaces 243 of the leads 240 of one semiconductor package 200 in the stack are electrically connected to respective ones of the fourth surfaces 244 of the leads 240 of another semiconductor package 200 in the stack. Such electrical connection may be accomplished through the use of a conductive epoxy, a solder paste, or the like between corresponding pairs of the third and fourth surfaces 243, 244. As will be recognized, the vertical stacking of the semiconductor packages 200 upon each other facilitates an increase in capacity.

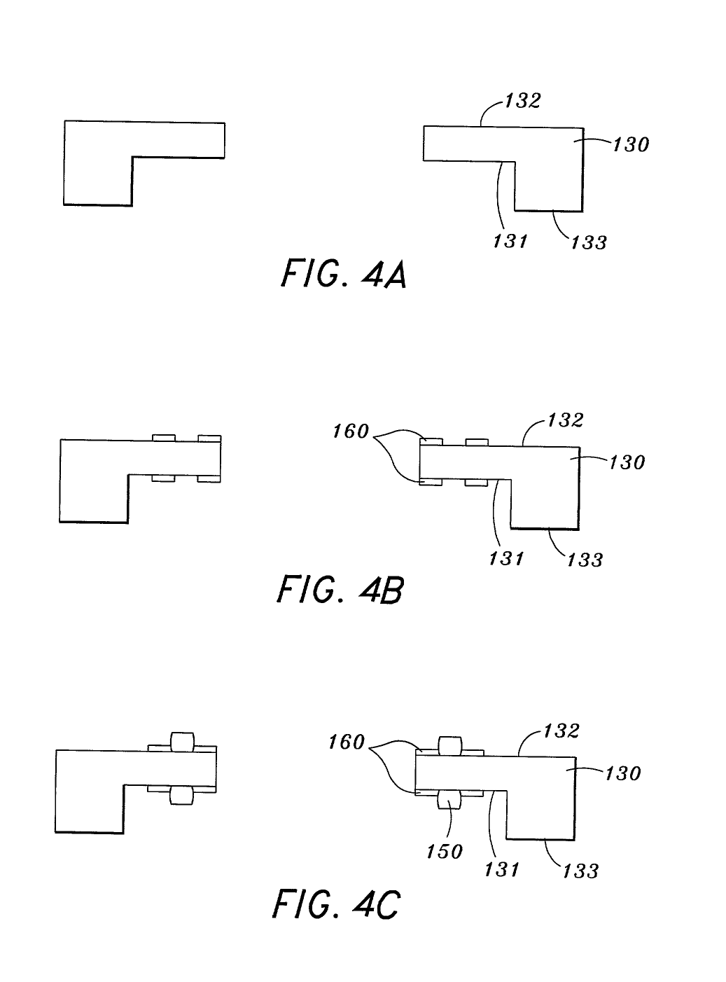

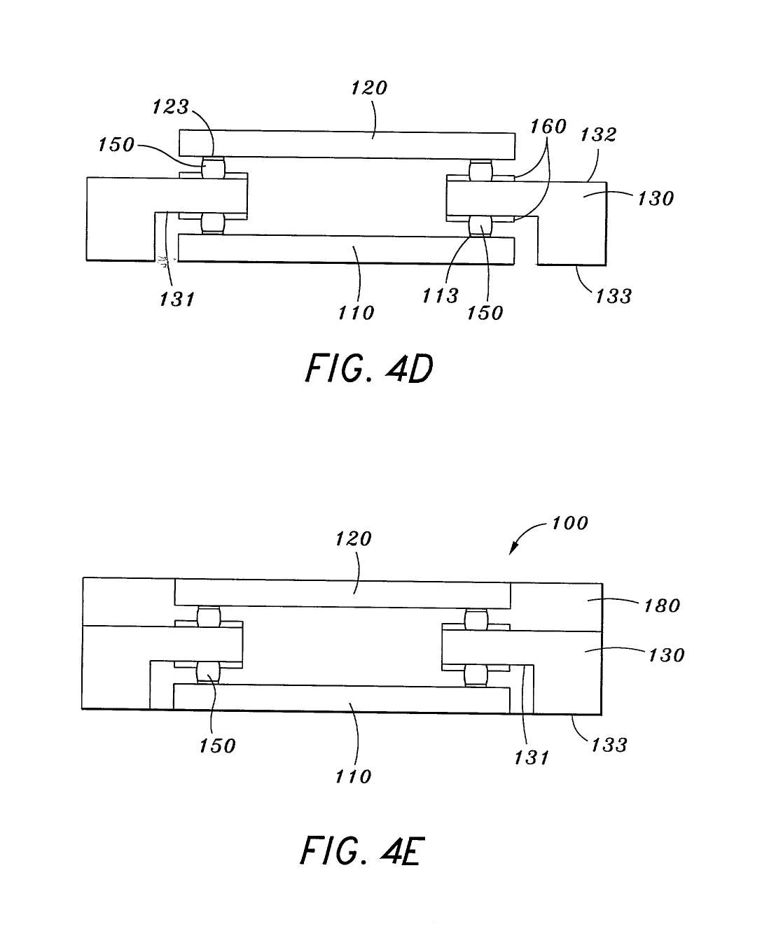

Referring now to FIGS. 4A through 4E, the manufacturing method for the semiconductor package 100 of the present invention preferably comprises the initial step of providing the leads 130 oriented relative to each other in the above-described manner (FIG. 4A). Thereafter, the protective layers 160 are coated on prescribed regions of the first and second surfaces 131, 132 of each of the leads 130 in the above-described manner (FIG. 4B). The conductive bumps 150 are then formed at each of the lower bump lands defined on portions of the first surfaces 131 by respective ones of the protective layers 160 applied thereto, and to the upper bump lands defined on portions of the second surfaces 132 by respective ones of the protective layers 160 applied thereto (FIG. 4C).

Subsequent to the formation of the conductive bumps 150, the bond pads 113 of the first semiconductor die 110 are electrically and mechanically connected to respective ones of the first surfaces 131 of the leads 30 via respective ones of the conductive bumps 150, with the bond pads 123 of the second semiconductor die 120 being electrically and mechanically connected to respective ones of the second surfaces 132 of the leads 130 by respective ones of the conductive bumps 150 (FIG. 4D). Finally, the encapsulating portion 180 is applied to the leads 130, first and second semiconductor dies 110, 120 and conductive bumps 150 in the above-described manner to protect the same from the external environment (FIG. 4E). As indicated above, in the semiconductor package 100, the bottom surface of the first semiconductor die 110 and third surface 133 of each of the leads 130 is exposed within the encapsulating portion 180, as is the top surface of the second semiconductor die 120. Those of ordinary skill in the art will recognize that as an alternative to forming the conductive bumps 150 at each of the lower and upper bump lands (FIG. 4C), the conductive bumps 150 may be formed directly on respective ones of the bond pads 113 of the first semiconductor die 110 and respective ones of the bond pads 123 of the second semiconductor die 120. The conductive bumps 150 formed directly on the first and second semiconductor dies 110, 120 may thereafter be mounted to respective ones of the leads 130, and more particularly to respective ones of the lower and upper bump lands defined thereby.

It will be recognized that a virtually identical manufacturing process is employed in relation to the semiconductor package 200 of the second embodiment, with the primary distinction being that the encapsulating portion 280 thereof is formed such that the fourth surface 244 of each lead 240 is exposed within the top surface of the encapsulating portion 280 along with the top surface of the second semiconductor package 220. For those semiconductor packages 200 constructed in accordance with the second embodiment of the present invention, a further step in the assembly method may comprise vertically stacking two or more semiconductor packages 200 upon each other in the above-described manner. As indicated above, in the semiconductor packages 100, 200 of the present invention, the use of the conductive bumps 150, 250 to facilitate the electrical and mechanical connection of the first and second semiconductor dies 110, 120 to the leads 130 and the first and second semiconductor dies 210, 220 to the leads 240 through the implementation of a flip die bonding technique enables the thickness of the semiconductor package 100, 200 to be substantially reduced.

This disclosure provides exemplary embodiments of the present invention. The scope of the present invention is not limited by these exemplary embodiments. Numerous variations, whether explicitly provided for by the specification or implied by the specification, such as variations in structure, dimension, type of material or manufacturing process may be implemented by one of skill in the art in view of this disclosure.

What is claimed is:

1. A semiconductor package comprising:
a plurality of leads, each of the leads defining:
a first surface;
a second surface disposed in opposed relation to the first surface; and
a third surface disposed in opposed relation to the second surface and laterally offset outwardly relative to the first surface;
a first semiconductor die defining opposed top and bottom surfaces;
a second semiconductor die defining opposed top and bottom surfaces;
a plurality of conductive connectors electrically and mechanically connecting the first semiconductor die to the first surfaces of the leads and the second semiconductor die to the second surfaces of the leads; and
an encapsulating portion applied to and at least partially encapsulating the leads, the first and second semiconductor dies, and the conductive connectors.

2. The semiconductor package of claim 1 wherein the conductive connectors each comprise a conductive bump.

3. The semiconductor package of claim 2 wherein the conductive bump is fabricated from material selected from the group consisting of:
gold; and
solder.

4. The semiconductor package of claim 1 wherein:
the first semiconductor die includes a plurality of bond pads disposed on the top surface thereof;
the second semiconductor die includes a plurality of bond pads disposed on the bottom surface thereof; and
the conductive connectors are used to electrically and mechanically connect the bond pads of the first semiconductor die to respective ones of the first surfaces of the leads and the bond pads of the second semiconductor die to respective ones of the second surfaces of the leads.

5. The semiconductor package of claim 4 wherein the conductive connectors each comprise a conductive bump.

6. The semiconductor package of claim 1 wherein:
each of the leads includes a first bump land formed at a prescribed region of the first surface thereof and a second bump land formed at a prescribed region of the second surface thereof;
the conductive connectors each comprise a conductive bump; and
the conductive bumps are fused to respective ones of the first and second bump lands of each of the leads.

7. The semiconductor package of claim 6 wherein each of the leads includes:
a first protective layer formed on at least a portion of the first surface thereof other than for the prescribed region including the first bump land; and
a second protective layer formed on at least a portion of the second surface thereof other than for the prescribed region including the second bump land.

8. The semiconductor package of claim 7 wherein the protective layer is selected from the group consisting of:
a polyimide;
titanium;
aluminum; and
a solder resist.

9. The semiconductor package of claim 1 wherein each of the leads includes:
a first protective layer coated on the first surface thereof about a respective one of the conductive connectors; and
a second protective layer coated on the second surface thereof about a respective one of the conductive connectors.

10. The semiconductor package of claim 9 wherein the protective layer is selected from the group consisting of:
a polyimide;
titanium;
aluminum; and
a solder resist.

11. The semiconductor package of claim 1 wherein the first and second semiconductor dies are identically sized.

12. The semiconductor package of claim 1 wherein the encapsulating portion is applied to the leads such that the third surface of each of the leads is exposed within the encapsulating portion.

13. The semiconductor package of claim 12 wherein the encapsulating portion is applied to the first and second semiconductor dies such that the bottom surface of the first semiconductor die and the top surface of the second semiconductor die are each exposed within the encapsulating portion.

14. The semiconductor package of claim 13 wherein the leads and first semiconductor die are oriented relative to each other such that the bottom surface of the first semiconductor die is substantially flush with the third surface of each of the leads.

15. The semiconductor package of claim 12 wherein:
each of the leads further defines an outer end which extends between the second and third surfaces thereof; and
the encapsulating portion is applied to the leads such that the outer end of each of the leads is exposed within the encapsulating portion.

16. The semiconductor package of claim 1 wherein each of the leads further defines a fourth surface disposed in opposed relation to the third surface and laterally offset outwardly relative to the second surface.

17. The semiconductor package of claim 16 wherein the encapsulating portion is applied to the leads such that the third and fourth surfaces of each of the leads are exposed within the encapsulating portion.

18. The semiconductor package of claim 17 wherein the encapsulating portion is applied to the first and second semiconductor dies such that the bottom surface of the first semiconductor die and the top surface of the second semiconductor die are each exposed within the encapsulating portion.

19. The semiconductor package of claim 18 wherein the second semiconductor die and the leads are oriented relative to each other such that the top surface of the second semiconductor die is substantially flush with the fourth surface of each of the leads.

20. The semiconductor package of claim 19 wherein the first semiconductor die and the leads are oriented relative to each other such that the bottom surface of the first semiconductor die is substantially flush with the third surface of each of the leads.

21. The semiconductor package of claim 17 further in combination with a second semiconductor package identically configured to the semiconductor package, the third surfaces of the leads of the second semiconductor package being electrically connected to respective ones of the fourth surfaces of the leads of the semiconductor package.

22. A method of fabricating a semiconductor package, comprising the steps of:
a) providing a plurality of leads, each of the leads having a first surface, a second surface disposed in opposed relation to the first surface, and a third surface disposed in opposed relation to the second surface and laterally offset outwardly relative to the first surface;
b) electrically and mechanically connecting a first semiconductor die to the first surface of each of the leads;
c) electrically and mechanically connecting a second semiconductor die to the second surface of each of the leads; and
d) applying an encapsulant to the first and second semiconductor dies and the leads to form an encapsulating portion which at least partially encapsulates the first and second semiconductor dies and the leads.

23. The method of claim 22 wherein the first and second semiconductor dies each include a plurality of bond pads, and:
step (b) comprises electrically and mechanically connecting the bond pads of the first semiconductor die to respective ones of the first surfaces of the leads through the use of conductive bumps; and
step (c) comprises electrically and mechanically connecting the bond pads of the second semiconductor die to respective ones of the second surfaces of the leads through the use of conductive bumps.

24. The method of claim 22 wherein step (d) comprises applying the encapsulant to the leads such that the third surface of each of the leads is exposed within the encapsulating portion.

25. The method of claim 21 wherein:
step (a) further comprises providing each of the leads with a fourth surface which is disposed in opposed relation to the third surface and laterally offset outwardly relative to the second surface; and
step (d) comprises applying the encapsulant to the leads such that the third and fourth surfaces of each of the leads are exposed within the encapsulating portion.

26. The method of claim 25 further comprising the step of:
e) electrically and mechanically connecting the third surfaces of the semiconductor package to respective ones of the fourth surfaces of another identically configured semiconductor package.
